(19) United States
(12) Patent Application Publication
(10) Pub. No.: US 2012/0286815 A1
(43) Pub. Date: Nov. 15, 2012

(54) Inspection Device Applying Probe Contact for Signal Transmission

(75) Inventors: Chian-Jung CHEN, Kaohsiung City (TW); Ching-Feng Hsieh, Taipei (TW)

(73) Assignee: Askey Computer Corporation, New Taipei City (TW)

(21) Appl. No.: 13/243,331

(22) Filed: Sep. 23, 2011

(30) Foreign Application Priority Data
May 12, 2011 (TW) 100116621

(51) Int. Cl. G01R 1/067

(52) U.S. Cl. 324/755.01

(57) ABSTRACT

An inspection device applying probe contact for signal transmission includes an inspection panel board; a probe base disposed on the inspection panel board and having a plurality of probes; a receiving moldboard disposed on the inspection panel board and including a fillister for receiving inspected portable electronic apparatus, and an open slot allocated facing the plurality of probes of the probe base, thereby enabling the plurality of probes to contact with corresponding signal terminals of the portable electronic apparatus; and a clamp unit disposed on the inspection panel board and consisting of an adjustable rod and a clamp block allocated at one end of the adjustable rod, the adjustable rod adjusting position of the clamp block, thereby clamping and properly positioning the portable electronic apparatus in the receiving moldboard.

### BACKGROUND OF THE INVENTION

1. Field of the Invention

This invention relates to inspection devices, and, more particularly, to an inspection device applying probe contact for signal transmission.

2. Description of Related Art

In a mass production of or before putting portable electronic apparatus in the market, a quality inspection procedure is generally taken to ensure the merchandise quality.

As shown in FIG. 1, which is a partial exterior view of a traditional inspection device for portable electronic apparatuses. The main body of the inspection device has a receiving mount 1 and a plurality of probes 10 disposed on one end side of the receiving mount 1. Guiding rails 11 are disposed at each of the opposing lateral sides of the receiving mount 1. The inspected portable electronic apparatus is guided by the guiding rails 11 and then positioned steadily in the receiving mount 1. The plurality of probes are enabled to be plug in the signal terminals of the portable electronic apparatus.

After a long-term use of the foresaid inspection device, the guiding rails 11 are getting worn out. Consequently, not only the inspected portable electronic apparatus cannot be positioned properly in the receiving mount 1, but also the plurality of probes 10 cannot be smoothly plugged in the signal terminals of the portable electronic apparatus, thereby causing the probes off position and further inspection error as well. Besides, the housing of the inspected electronic product is easily scratched by the worn-out guiding rails 11.

### SUMMARY OF THE INVENTION

In view of the drawbacks of the prior art mentioned above, it is therefore an objective of this invention to provide an inspection device applying probe contact for signal transmission, providing advantages of avoiding structure thereof to be worn out due to a long period of heavy use of the inspection device, and further ensuring to maintain the appearance of the inspected portable electronic apparatus and enhancing inspection efficiency as well.

To achieve foresaid and other objectives, the present invention provides an inspection device applying probe contact for signal transmission, comprising: an inspection panel board; a probe base disposed on the inspection panel board and including a plurality of probes; a receiving moldboard disposed on the inspection panel board and including a fillister for receiving inspected portable electronic apparatus, and an open slot facing the plurality of probes of the probe base for enabling the plurality of probes to contact with signal terminals of the portable electronic apparatus; and a clamp unit disposed on the inspection panel board and including an adjustable rod and a clamp block disposed on one end of the adjustable rod, the adjustable rod adjusting position of the clamp block, thereby clamping and properly positioning the portable electronic apparatus received in the receiving moldboard.

The fillister of the foresaid inspection device applying probe contact for signal transmission has a power supply open chamber therein for containing a power supply module. The power supply module is for providing the portable electronic apparatus with needed power. Furthermore, a driving cylinder is disposed on another side of the inspection panel board opposing to the side whereon the probe base, the receiving moldboard, and clamp unit are disposed, and the driving cylinder is for the power supply module to come out from the power supply open chamber, thereby enabling a power supply part of the power supply module to contact with the power supply terminals of the portable electronic apparatus.

The receiving moldboard of the foresaid inspection device applying probe contact for signal transmission is made of Polyoxymethylene (POM), or the surface of the receiving moldboard is plated with Polytetrafluoroethene (PTFE).

According to the stated aforesaid, the inspection device applying probe contact for signal transmission of the present invention is capable of steadily positioning the inspected portable electronic apparatus, as well enhancing contact quality between the probes and the portable electronic apparatus, also the power supply open chamber disposed on the fillister for containing the power supply module provides advantage of saving the procedure of installing power supply battery for inspected portable electronic apparatus, thereby greatly enhancing inspection efficiency. In addition, by using said POM and PTFE materials, avoiding the risk of scratching the housing of the portable electronic apparatus.

### BRIEF DESCRIPTION OF DRAWINGS

The invention can be more fully understood by reading the following detailed description of the preferred embodiments, with reference made to the accompanying drawings, wherein:

FIG. 1 is a partial exterior view of a traditional inspection device for portable electronic apparatus;

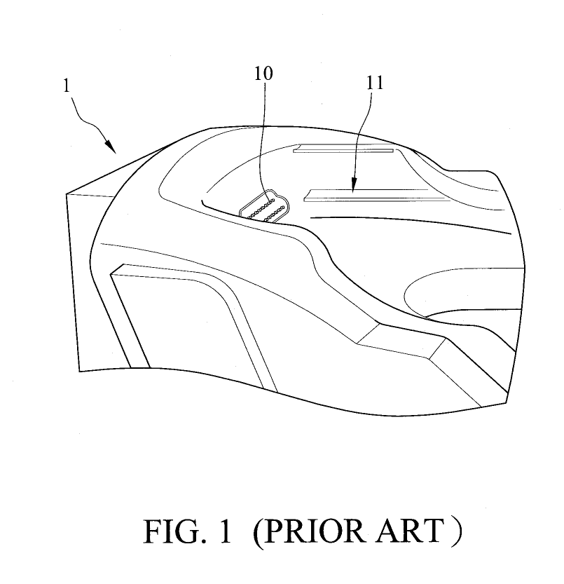

FIG. 2 is an exterior view of an inspection device applying probe contact for signal transmission of the present invention;

FIG. 3 is an exterior view of the inspection device applying probe contact for signal transmission of the present invention, depicting an inspected portable electronic device is properly clamped and positioned;

FIG. 4 is a diagram depicting assembling of partial elements in another view of the FIG. 2; and

FIG. 5 is a diagram depicting a status of inspection process, applying the inspection device applying probe contact for signal transmission of the present invention on a portable electronic apparatus.

### DETAILED DESCRIPTION OF PREFERRED EMBODIMENTS

The following illustrative embodiments are provided to illustrate the disclosure of the present invention; those in the art can apparently understand these and other advantages and effects after reading the disclosure of this specification. The present invention can also be performed or applied by other different embodiments. The details of the specification may be on the basis of different points and applications, and numerous modifications and variations can be devised without departing from the spirit of the present invention.

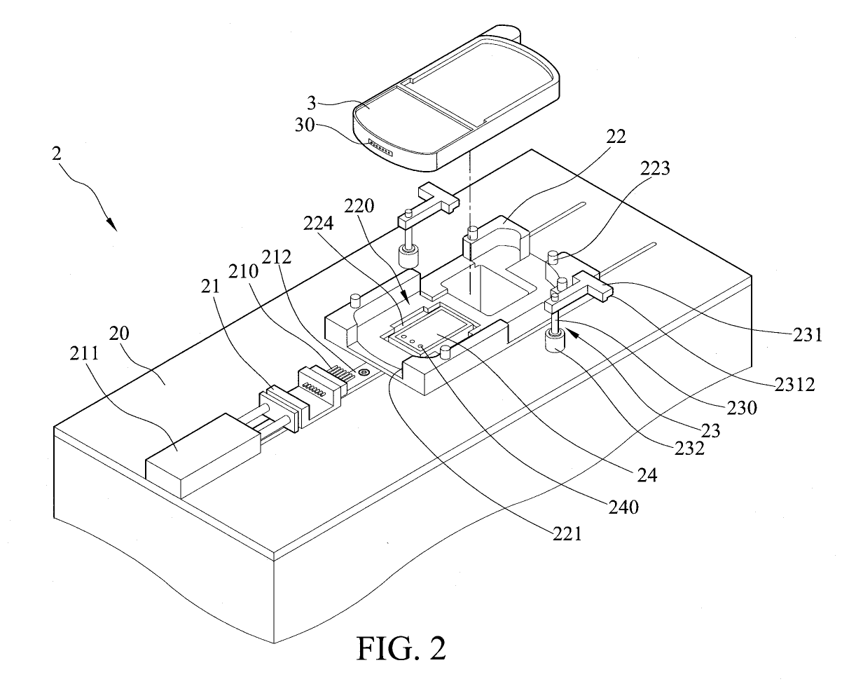

Please refer to FIG. 2, which is an exterior view of an inspection device applying probe contact for signal transmission according to the present invention.

The inspection device 2 applying probe contact for signal transmission of the present invention is for processing function inspection on an inspected portable electronic apparatus 3. The inspection device 2 comprises an inspection panel board 20, a probe base 21, a receiving moldboard 22, and a clamp unit 23.

The probe base 21, the receiving moldboard 22, and the clamp unit 23 may be disposed on the inspection panel board 20.

The probe base 21 has a plurality of probes 210. In an embodiment of the present invention, the movement of the probe base 21 is controlled by a driving cylinder 211 disposed on the inspection panel board 20, in order to make the probe base 21 to move toward a predetermined direction. The inspection panel board 20 further has a guiding track 212 disposed thereon.

The receiving moldboard 22 comprises a fillister 220 for receiving the portable electronic apparatus 3, and an open slot 221 facing the plurality of probes 210 of the probe base 21. The probe base 21 is driven by the driving cylinder 211 to move toward/away from the open slot 221 along the guiding track 212, thereby enabling the plurality of probes 210 to slide in or out of the open slot 221 of the receiving moldboard 22. Consequently, the probes 210 are able to contact signal terminals 30 of the portable electronic apparatus 3 received and positioned in the receiving moldboard 22.

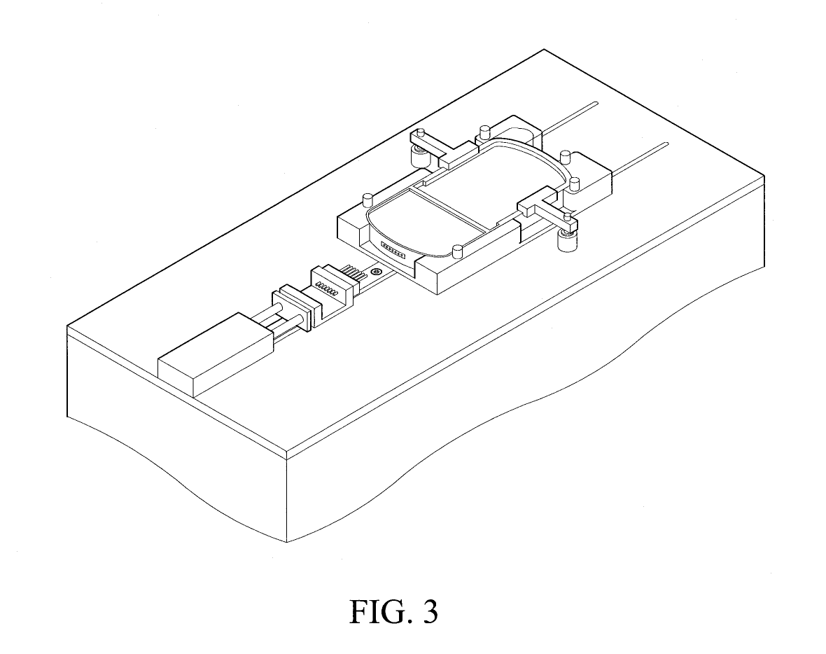

The clamp unit 23 comprises a adjustable rod 230 and a clamp block 231 disposed at one end of the adjustable rod 230. The adjustable rod 230 is for adjusting the position of the clamp block 231, thereby clamping and properly positioning the portable electronic apparatus 3 in the receiving moldboard 22. In the present embodiment, the movement of the adjustable rod 230 is controlled by a rotary cylinder 232. The rotary cylinder 232 is disposed on the inspection panel board 20 for controlling the adjustable rod 230 to rotate and adjust to a predetermined status, thus enabling the clamp block 231 to clamp and properly position the portable electronic apparatus 3 received in the receiving moldboard 22, as shown in FIG. 3. Moreover, in the present embodiment, the clamp block 231 has a clamping part 2312 for clamping the housing of the portable electronic apparatus 3 and thus enhancing the steadiness. When the driving cylinder 211 is driving the probe base 21 to move toward the open slot 221, the plurality of probes 210 can smoothly contact with the signal terminals 30 of the portable electronic apparatus 3 received in the receiving moldboard 22.

Furthermore, as shown in FIG. 2, a plurality of guiding rods 223 are disposed around the periphery of the fillister 220 of the receiving moldboard 22, a level gap is formed between the guiding rods 223 and the fillister 220, and the guiding rod 223 enables the inspected portable electronic apparatus to be guided smoothly into the fillister 220 of the receiving moldboard 22.

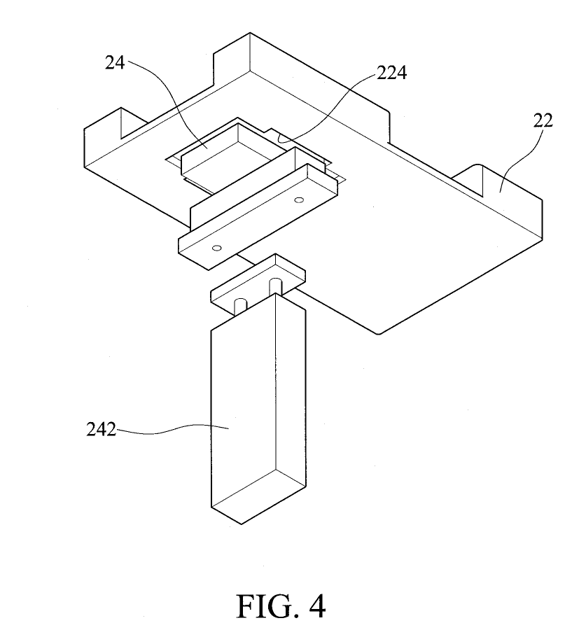

In addition, the inspection device 2 applying probe contact for signal transmission further comprises a feature function of providing an inspected portable device with power supply, namely comprising a power supply open chamber 224 in the fillister 220 of the receiving moldboard 22 for containing a power supply module. The power supply module is for providing the portable electronic apparatus with needed power. In the present embodiment, the power supply module is a charging circuit board 24. In order to have a power supply part 240 of the charging circuit board 24 to contact with a power supply terminal (not shown) of the portable electronic apparatus 3 positioned in the receiving moldboard 22, as shown in FIG. 4, a driving cylinder 242 is disposed on another side of the inspection panel board 20 opposing to the side whereon the probe base 21, the receiving moldboard 22, and the clamp unit 23 are disposed. The driving cylinder 242 is for the charging circuit board 24 to come out from the power supply open chamber 224, thereby enabling the power supply part 240 of the charging circuit board 24 to contact with the power supply terminal of the portable electronic apparatus 3.

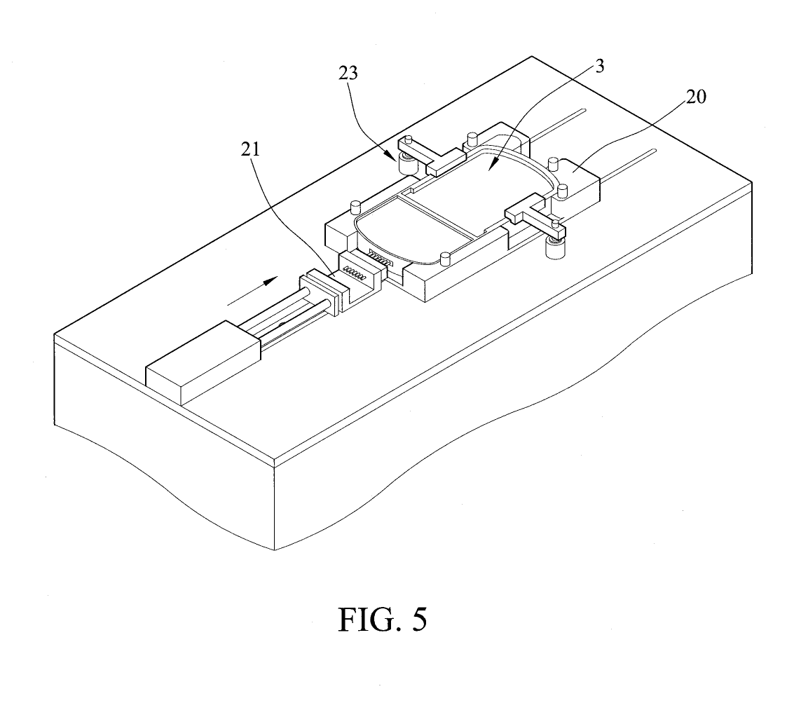

As shown in FIG. 5, which depicts a status of inspection process, applying the inspection device applying probe contact for signal transmission of the present invention on a portable electronic apparatus. According to the stated aforesaid, the probe base 21, the receiving moldboard 22, and the clamp unit 23 provide the inspected portable electronic apparatus with enhanced steadiness, as well improved contact quality between the probes and the portable electronic apparatus. Besides, since the fillister has a power supply open chamber disposed therein for containing the power supply module, the procedure of installing a power supply battery for the inspected portable electronic apparatus is extremely simplified, and consequently enhancing the inspection efficiency tremendously.

Besides, the inspection device applying probe contact for signal transmission of the present invention not only can use the driving cylinder 211 to move the probe base 21 on along the guiding track 212 as shown in FIG. 2, but also a clamp can be used to replace the driving cylinder 211.

Moreover, in order to prevent the portable electronic apparatus from being scratched on the housing thereof while being positioned in the receiving moldboard 22, the receiving moldboard 22 can be plated with Polytetrafluoroethene (PTFE) or Polyoxymethylene (POM); accordingly the inspection device applying probe contact for signal transmission of the present invention further provides a feature advantage of preventing risk of scratching the housing of the portable electronic apparatus.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. An inspection device applying probe contact for signal transmission, comprising:
an inspection panel board;
a probe base disposed on the inspection panel board and comprising a plurality of probes;
a receiving moldboard disposed on the inspection panel board and comprising a fillister for receiving an inspected portable electronic apparatus therein, and an open slot facing the plurality of probes of the probe base for the plurality of probes to contact with corresponding signal terminals of the inspected portable electronic apparatus; and
a clamp unit disposed on the inspection panel board and comprising an adjustable rod and a clamp block disposed at one end of the adjustable rod, the adjustable rod adjusting a position of the clamp block for clamping and positioning the portable electronic apparatus received in the receiving moldboard.

2. The inspection device of claim 1, wherein the receiving moldboard comprises a plurality of guiding rods disposed on a periphery of the fillister.

3. The inspection device of claim 2, wherein a level gap exists between the guiding rods and the fillister.

4. The inspection device of claim 1, further comprising a rotary cylinder for controlling the adjustable rod to be adjusted to a predetermined status, thereby enabling the clamp block to clamp and position the portable electronic apparatus received in the receiving moldboard.

5. The inspection device of claim 1, wherein the fillister comprises a power supply open chamber for containing a power supply module, and the power supply module is for providing the portable electronic apparatus with needed power.

6. The inspection device of claim 5, wherein the power supply module is a charging circuit board.

7. The inspection device of claim 5, wherein a driving cylinder is disposed on another side of the inspection panel board opposing to the side whereon the probe base, the receiving moldboard, and clamp unit are disposed, and the driving cylinder is for controlling the power supply module to come out from the power supply open chamber, thereby enabling a power supply part of the power supply module to contact with a power supply terminal of the portable electronic apparatus in the receiving moldboard.

8. The inspection device of claim 1, further comprising a driving cylinder and a guiding track both disposed on the inspection panel board, the driving cylinder enabling the probe base to move on along the guiding track, and enabling the plurality of probes to slide in or out of the fillister of the receiving moldboard.

9. The inspection device of claim 1, further comprising a clamp and a guiding track, the clamp allowing the probe base to move on along the guiding track, thereby enabling the plurality of probes to slide in or out of the fillister of the receiving moldboard.

10. The inspection device of claim 1, wherein the receiving moldboard is made of Polyoxymethylene (POM), or the receiving moldboard is plated with Polytetrafluoroethene (PTFE).

11. The inspection device of claim 1, wherein the clamp block comprises a clamping part for clamping a housing of the portable electronic apparatus.
